(19) United States
(12) Patent Application Publication
(10) Pub. No.: US 2014/0199203 A1
(43) Pub. Date: Jul. 17, 2014

(54) HIGH-PURITY LANTHANUM, METHOD FOR PRODUCING SAME, SPUTTERING TARGET COMPRISING HIGH-PURITY LANTHANUM, AND METAL GATE FILM COMPRISING HIGH-PURITY LANTHANUM AS MAIN COMPONENT

(71) Applicants: Masahiro Takahata, Ibaraki (JP); Kazuyuki Satoh, Ibaraki (JP); Takeshi Gohara, Ibaraki (JP); Satoyasu Narita, Ibaraki (JP)

(72) Inventors: Masahiro Takahata, Ibaraki (JP); Kazuyuki Satoh, Ibaraki (JP); Takeshi Gohara, Ibaraki (JP); Satoyasu Narita, Ibaraki (JP)

(73) Assignee: JX NIPPON MINING & METALS CORPORATION, Tokyo (JP)

(21) Appl. No.: 14/238,209

(22) PCT Filed: Sep. 4, 2012
(86) PCT No.: PCT/JP2012/072409

§ 371 Date: Feb. 11, 2014

(30) Foreign Application Priority Data
Sep. 28, 2011 (JP) 2011-212930

(51) Int. Cl. C22C 28/00; C23C 14/34; C22B 59/00

(52) U.S. Cl. CPC C22C 28/00; C22B 59/00; C23C 14/3407
USPC 420/416; 75/10.13; 204/298.13

(57) ABSTRACT

A high-purity lanthanum, characterized by having a purity of 5N or more excluding rare earth elements and gas components, and α-ray count number of 0.001 cph/cm² or less. A method for producing the high-purity lanthanum characterized by obtaining lanthanum crystal by subjecting a crude lanthanum metal raw material having a purity of 4N or less excluding the gas component to molten salt electrolysis at a bath temperature of 450 to 700° C., subjecting the lanthanum crystal to de-salting treatment, and removing volatile substances by performing electron beam melting, wherein the high-purity lanthanum has a purity of 5N or more excluding rare earth elements and gas components, and α-ray count number of 0.001 cph/cm² or less. The object of the present invention is providing a technique capable of efficiently and stably providing a high-purity lanthanum with low α-ray, a sputtering target made from the high-purity lanthanum, and a metal gate thin film having the high-purity lanthanum as the main component.

### TECHNICAL FIELD

The present invention relates to high-purity lanthanum, a method for producing high-purity lanthanum, a sputtering target comprising high-purity lanthanum, and a metal gate film comprising high-purity lanthanum as main component.

### BACKGROUND ART

Lanthanum (La) is one of rare earth elements that exists in the form of mixed complex oxides as mineral resources in earth's crust. Rare earth elements were named as such since they were originally isolated from relatively rare minerals. However, their existence is not so rare if whole of earth's crust is taken into account.

Lanthanum, of which atomic number is 57, is a silvery white metal with atomic weight of 138.9 and has a multi hexagonal close-packed structure at ambient temperature. It has the melting point of 921° C., boiling point of 3500° C., and density of 6.15 g/cm³, and its surface is oxidized in air. It melts slowly in water, and is soluble in hot water as well as in acid. It is not ductile but exhibits slight malleability. Its specific resistance is 5.70×10⁻⁶Ω cm. It combusts at 445° C. and above and forms an oxide (La₂O₃) (see Encyclopedia of Physical Chemistry).

Rare earth elements in general are stable as compounds with oxidation number of three, and lanthanum is also trivalent. Recently, a lot of research and development have focused on lanthanum as electronic material such as metal gate material and high dielectric constant material (High-k), making it one of the metals that is drawing a lot of attention.

Metallic lanthanum has the problem of being readily oxidized during the purification process, and as such, is a difficult material to work with in a highly purified form. Hence, no highly purified product of lanthanum has been made available to date. In addition, metallic lanthanum turns black by oxidation in a short period of time when left exposed to air, creating additional problem for handling.

In the next generation MOSFET, gate insulator needs to become even thinner than it currently is. SiO₂, which has been traditionally used as gate insulator, however, is approaching its limits in usefulness in that it is increasingly becoming difficult to function properly at the required thinness, because of the increase in the leak current due to tunnel effect.

For this reason, HfO₂, ZrO₂, Al₂O₃ and La₂O₃ having high dielectric constant, high thermal stability and high energy barrier against electron holes and electrons in silicon, have been proposed as its potential alternatives. Among these materials, La₂O₃ is considered to be especially promising, and thus, its electrical characteristics have been studied, and its potential as gate insulator in the next generation MOSFET has been reported (see non-patent document 1). However, in this particular non-patent document, the subject of the study is limited to La₂O₃ film, and the characteristics and behavior of lanthanum element are not explored.

On the other hand, a technology in which halogenated rare earth metals are reduced by calcium or hydrogenated calcium was proposed about 2 decades ago as a method for isolating rare earth metals. This document listed lanthanum as an example of rare earths. However, the technology was a rudimentary one involving slag separating jig as a means of separating slag, and did not particularly disclose much about the problems associated with the use of metallic lanthanum element as well as the method for its purification.

As discussed above, the use of lanthanum (lanthanum oxide) is still in its early days and more research is required. In studying the property of lanthanum (lanthanum oxide), having a metallic lanthanum itself as a sputtering target material would be highly beneficial because it would enable the formation of lanthanum thin film on a substrate and facilitate the research into the behavior of its interface with the silicon substrate as well as the properties of high dielectric constant gate insulator and the like made from lanthanum compounds produced. It would also greatly enhance the freedom of its use in various final products.

However, the problem of oxidation that can occur rapidly, i.e., in about 10 minutes, when exposed to air would persist even if such a lanthanum sputtering target is produced. Once the oxidized film is formed on the target, it would result in the reduction of electric conductivity and lead to defects in sputtering. Moreover, if the target is left exposed to air for a long period of time, it would react with the moisture in the air and can become covered with white hydroxide powder, which in turn makes sputtering impossible.

For this reason, measures for preventing oxidation, such as packing in vacuum or covering with oil, need to be taken immediately after the production of target. However, these are extremely cumbersome processes. Due to these problems, the target material using lanthanum element still has not been realized.

Furthermore, generation of nodules on the surface of the target poses another problem when forming a film by sputtering with lanthanum target. These nodules elicit abnormal discharge, generating particles from the eruption of the nodules and the like.

Generation of particles in turn can increase the defect rate of metal gate films, semi-conductor elements and devices. Especially problematic is the presence of carbon (graphite), which is a solid. Graphite is conductive and is difficult to be detected; however, improvement is required to reduce its presence.

Moreover, although lanthanum is a difficult material to prepare in highly purified form as discussed earlier, it is preferable to reduce the content of Al, Fe and Cu in addition to carbon (graphite) mentioned above, in order to take full advantage of the property of lanthanum. Furthermore, the presence of alkaline metals, alkali earth metals, transition metal elements, high melting point metal elements, and radioactive elements all adversely affect the property of semi-conductor and therefore need to be reduced. From these considerations, the purity of lanthanum is preferably 5N or more.

However, a problem exists in the extreme difficulty of removing lanthanoids other than lanthanum. Fortunately, minor contamination of lanthanoids other than lanthanum poses no major issues since their properties are similar enough to that of lanthanum. Likewise, minor contamination of gas components also poses no major problems. Gas component is generally very difficult to remove, and it is customary not to include the contribution from the gas component when indicating the purity.

Topics such as the physical property of lanthanum, production method for highly purified lanthanum, behavior of impurities in lanthanum target, have not been extensively explored to date. Then, it is highly desirable that these problems are adequately addressed as soon as possible. In addition, with the high-density and high-capacity semi-conductor apparatus of today, the danger of software error occurring, due to the influence of α-ray emitted from the materials in close proximity to the semi-conductor chip, is increasing. For this reason, material with less α-ray is needed.

A number of disclosures exist pertinent to technologies aiming at reducing α-ray. These involve different types of materials, but they are introduced below.

Patent Document 1 below discloses a production method for low α-ray tin, that involves making an alloy of tin and lead having α-ray amount of 10 cph/cm², followed by refining in which lead contained in tin is removed.

The objective of this technology is in reducing the amount of α-ray by diluting the amount of ²¹⁰Pb in the tin through addition of high purity Pb. However, this case calls for a very complicated procedure of adding Pb to the tin followed by further removal of Pb. Moreover, although it discloses a significantly reduced amount of α-ray, it is measured after three years from the refining of tin. One way of interpreting this is that one has to wait three years before the tin with the reduced amount of α-ray could be used. If this is the case, this method cannot be regarded as efficient enough method for industrial application.

Patent Document 2 below discloses that addition of 10 to 5000 ppm of a material selected from Na, Sr, K, Cr, Nb, Mn, V, Ta, Si, Zr, and Ba to Sn—Pb alloy solder reduces the count number of α particle radiation to 0.5 cph/cm² or less.

However, the reduction of the count number of a particle radiation by the addition of such material remain at the level of 0.015 cph/cm², a level far below that expected in the materials to be used in semi-conductor apparatus of today.

Another issue is the fact that elements that are preferably not contained in semi-conductors, such as alkaline metal elements, transition metal elements and heavy metal elements, are being used as the additives. Thus, this material has to be regarded as low quality material for use in assembling semi-conductor apparatus.

Patent Document 3 below discloses reducing the count number of a particle radiation emitted from an extra fine wire of solder to 0.5 cph/cm² or less, and using it as the connecting wire for semi-conductor apparatus and the like. However, the level of reduction of the count number of α particle radiation is far below that of what is expected in the materials to be used in semi-conductor apparatus of today.

Patent Document 4 below discloses obtaining high-purity tin having low lead concentration and having α-ray count number of lead of 0.005 cph/cm² or less by performing electrolysis using highly purified sulfuric acid and hydrochloric acid such as high-grade sulfuric acid and high-grade hydrochloric acid as the electrolyte, and high-purity tin as the anode. If cost is ignored and high-purity raw materials (reagents) are used, high-purity materials can, of course, be obtained. However, the lowest α-ray count number shown for the sedimented tin in the Examples of Patent Document 4 is still 0.002 cph/cm². Thus, it still does not reach the level expected, despite its high cost.

Patent Document 5 below discloses a method comprising precipitating metastannic acid by adding nitric acid to heated aqueous solution containing crude metallic tin, filtering and washing the precipitate, dissolving the washed metastannic acid into hydrochloric acid or hydrofluoric acid, and obtaining metallic tin having a purity of 5N or more by electrowinning using the dissolved solution as an electrolyte. It discloses in vague terms that the technology can be applied to uses for semi-conductor apparatus. However, there are no particular comments regarding the restrictions on the radioactive elements U and Th, and the count number of □□ α particle radiation, demonstrating very low level of interest regarding these points.

Patent Document 6 below discloses a technology wherein the amount of Pb contained in Sn that comprises a solder alloy is reduced, and Bi, Sb, Ag, or Zn is used as alloy material. However, in this case, even though Pb is reduced as much as possible, no fundamental measures are provided for the problem of the count number of α particle radiation caused by inevitable Pb contamination.

Patent Document 7 below discloses tin produced by electrolysis using high-grade sulfuric acid reagent, having a purity of 99.99% or more and the count number of α particle radiation of 0.03 cph/cm² or less. If cost is ignored and high-purity raw materials (reagents) are used, high-purity materials can be obtained as a result. However, despite the high cost, the lowest α-ray count number of precipitated tin shown in Examples of Patent Document 7 is still 0.003 cph/cm², and does not reach the level of what is expected.

Patent Document 8 below discloses lead for brazing filler metal for use in semi-conductor apparatus having a purity of 4 nines purity or more, radioisotope of no more than 50 ppm, and count number of a particle radiation of 0.5 cph/cm² or less. In addition, in Patent Document 9 below, tin for brazing filler metal for use in semi-conductor apparatus having a purity of 99.95% or more, radioisotope of no more than 30 ppm, and count number of α particle radiation of 0.2 cph/cm² or less is disclosed.

These, however, have lax maximum permissible amounts for count number of α particle radiation that are not good enough for material to be used in semi-conductor apparatus of today.

Cited Publication 10 discloses an example of Sn whose purity is 99.999% (5N). However, this Sn concerns a metal plug material for seismic isolation structure and there are no disclosures in regard to the restrictions on radioactive elements U and Th as well as count number of α particle radiation. Thus, such a material cannot be used for materials in assembling semi-conductor apparatus.

Cited Publication 11 discloses a method for removing technetium from nickel that is contaminated with a large amount of technetium (Tc), uranium and thorium, by using graphite or activated charcoal powder. The reason behind this method is the fact that technetium cannot be removed by electrolytic refinement method, because it coprecipitates with nickel on the cathode. In other words, technetium, a radioisotope contained in nickel, cannot be removed by electrolytic refinement method.

This technology, however, is restricted to the problem of nickel contaminated with technetium, and cannot be applied to other substances. In addition, this technology relates to treatment of industrial wastes that are harmful to humans, and is considered to be too rudimentary for a technology to be employed in high-level purification required for materials used in semi-conductor apparatus.

Cited Publication 12 discloses a production method for rare earth metals in which halides of rare earths are reduced by calcium or hydrogenated calcium, and the obtained rare earth metals and slag are separated, wherein a slag separating jig is immersed in the molten slag after which the slag is solidified and integrated into the slag separating jig, and the slag is removed together with the separating jig. The separation of slag is performed at a high temperature of 1000 to 1300° C. and electron beam melting is not performed.

The methods described above all utilize different purification strategies that can only achieve a low level purification. Therefore, it is highly unlikely that they can be used to realize the reduction of a particle radiation.

### CITATION LIST

Patent Document 1: Japanese Patent Publication No. 3528532
Patent Document 2: Japanese Patent Publication No. 3227851
Patent Document 3: Japanese Patent Publication No. 2913908
Patent Document 4: Japanese Patent Publication No. 2754030
Patent Document 5: Japanese Unexamined Patent Application No. H11-343590
Patent Document 6: Japanese Unexamined Patent Application No. H9-260427
Patent Document 7: Japanese Unexamined Patent Application No. H1-283398
Patent Document 8: Japanese Examined Patent Publication No. S62-47955
Patent Document 9: Japanese Examined Patent Publication No. S62-1478
Patent Document 10: Japanese Unexamined Patent Application No. 2001-82538
Patent Document 11: Japanese Unexamined Patent Application No. H7-280998
Patent Document 12: Japanese Unexamined Patent Application No. S63-11628
Non-Patent Document 1: Eisuke Tokumitsu et. al. “Study of oxide materials for High-k gate insulator”. Research material for The Institute of Electrical Engineers of Japan, Committee on Electronic Materials. Vol. 6-13, page 37-41. Sep. 21, 2001.

### SUMMARY OF THE INVENTION

### Technical Problem

The present invention aims at providing a technique capable of stably providing a production method for high-purity lanthanum, high-purity lanthanum, a sputtering target made from the high-purity lanthanum, a metal gate film formed using the sputtering target, and semi-conductor elements and devices, by reducing α-ray count number of the metal gate film to 0.001 cph/cm² or less thereby excluding the effect of the α-ray to semi-conductor chips as much as possible.

### Solution to Problem

The present invention provides,

(1) a high-purity lanthanum characterized by having a purity of 5N or more excluding rare earth elements and gas components, and α-ray count number of 0.001 cph/cm² or less,

The present invention further provides,

(2) the high-purity lanthanum according to (1) above, characterized by having Pb content of 0.1 wtppm or less, Bi content of 0.01 wtppm or less, Th content of 0.001 wtppm or less, and U content of 0.001 wtppm or less.

The present invention further provides,

(3) the high-purity lanthanum according to (1) or (2), characterized by having Al, Fe, Cu contents of 1 wtppm or less, respectively, and
(4) the high-purity lanthanum according to any one of (1) to (3) above, characterized by having a total content of W, Mo and Ta of 10 wtppm or less. These impurities adversely affect the physical characteristics of semi-conductors, and therefore are elements that need to be reduced as much as possible.

The present invention further provides,

(5) a sputtering target comprising the high-purity lanthanum according to (1) to (4) above,
(6) a metal gate film formed using the sputtering target according to (5) above,
(7) semi-conductor elements and devices equipped with the metal gate film according to (6) above,
(8) a method for producing the high-purity lanthanum characterized by obtaining lanthanum crystal by subjecting a crude lanthanum metal raw material having a purity of 4N or less excluding the gas component to molten salt electrolysis at a bath temperature of 450 to 700° C., subjecting the lanthanum crystal to de-salting treatment, and removing volatile substances by performing electron beam melting, wherein the high-purity lanthanum has a purity of 5N or more excluding rare earth elements and gas components, and α-ray count number of 0.001 cph/cm² or less,
(9) the method for producing the high-purity lanthanum according to (8) above, characterized by using an electrolytic bath comprising potassium chloride (KCl), lithium chloride (LiCl) and lanthanum chloride (LaCl₃) as the molten salt electrolytic bath,
(10) the method for producing the high-purity lanthanum according to (8) or (9) above, characterized by performing molten salt electrolysis using an anode made from Ta, and
(11) the method for producing high-purity lanthanum according to any one of (8) to (10) above, characterized by performing de-salting treatment that separates metal and salt utilizing the difference in vapor pressure by vacuum heating in a heating furnace at a temperature of 850° C. or less.

The present invention encompasses all of the novel substances described above as high-purity lanthanum. LaOx film is formed in the majority of cases where it is used as gate insulator in MOSFET. In forming such a film, high-purity metallic lanthanum is required so that one can have more freedom in the formation of the film to form any types of film. The invention of the present application can provide material that suits this purpose.

Rare earth elements belonging to lanthanoids include Sc, Y, Ce, Pr, Nd, Pm, Sm, Eu, Gd, Tb, Dy, Ho, Er, Tm, Yb, and Lu in addition to La, and their similarity in physical properties make it difficult to separate them from La. Especially, Ce, being very similar to La, is extremely difficult to remove.

However, since these rare earth elements have similar properties, minor contaminations pose no problems in using them in materials for electronic component, as long as the total content of rare earth elements are kept at no more than 100 wtppm. Thus, this level of contamination of rare earth elements is tolerated in the lanthanum of the invention of the present application.

Generally, gas components include C, N, O, S and H. These can exist as individual elements or as compounds (such as CO, CO₂, SO₂) or as compounds with constituent elements. Since these gas component elements have smaller atomic weight and atomic radius, they do not largely affect the properties of the material as contaminating impurities, as long as they are not contained in excessive amounts. Thus, the purity is customarily indicated as the purity excluding the gas components. The purity of lanthanum in the invention of the present application is also indicated as 5N or more excluding gas components.

The high-purity lanthanum described above can be achieved by a process characterized in that: a crude lanthanum metal raw material having a purity of 3N or less, excluding gas components, is used as the starting material; the material is subjected to molten salt electrolysis at a bath temperature of 450-700° C. to produce lanthanum crystals; the lanthanum crystals are subsequently desalted; and electron beam melting is then performed to remove volatile substances.

As to the molten salt electrolytic bath, one can use more than one type of electrolytic bath selected from general potassium chloride (KCl), lithium chloride (LiCl), sodium chloride (NaCl), magnesium chloride (MgCl₂), calcium chloride (CaCl₂), and lanthanum chloride (LaCl₃). Furthermore, an anode made from Ta can be used in molten salt electrolysis.

In addition, for the desalting process, separation of metal and salt by utilizing the difference in vapor pressures can effectively be performed by using a heating furnace and applying heat in vacuum at a temperature of 850° C. or less.

The invention of the present application provides a sputtering target made from the high-purity lanthanum, a metal gate film formed using the sputtering target, and semi-conductor elements and devices equipped with the metal gate film.

In other words, one can obtain a metal gate film having the same ingredients as the target by sputtering the target. These sputtering target, metal gate film and semi-conductor elements and devices equipped with the metal gate film are all novel substances and are included in the invention of the present application.

As described above, LaOx film is formed in the majority of cases where it is used as gate insulator in MOSFET. In forming such a film, high-purity metallic lanthanum is required so that one can have more freedom in the formation of the film to form any types of film.

The invention of the present application can provide material that suites this requirement. Accordingly, the high-purity lanthanum of the invention of the present application includes those produced in combination with other substances when preparing targets.

### Effects of Invention

The present invention achieves the excellent effect of stably providing, a high-purity lanthanum, a sputtering target made from the high-purity lanthanum, a metal gate film formed using the sputtering target, and semi-conductor elements and devices equipped with the metal gate film wherein the α-ray count number is reduced to 0.001 cph/cm² or less thereby excluding the influence of α-ray to the semi-conductor chip as much as possible.

### BRIEF DESCRIPTION OF THE DRAWINGS

FIG. 1 is a diagram showing an example of molten salt electrolysis apparatus.

FIG. 2 is a figure (a picture) showing the shape of the crystal that changes depending on the current density during the electrolysis.

FIG. 3 is a schematic figure explaining the production process of the high-purity lanthanum of the present invention.

FIG. 4 is a figure depicting the relationship between the time and α-ray count number of the commercially available La and the low α emitting La measured in Example 1 of the invention of the present application.

### DESCRIPTION OF EMBODIMENTS

In the present invention, a crude lanthanum metal starting material having a purity of 4N or less excluding gas components, can be used as the high-purity lanthanum staring material. These starting materials contain Li, Na, K, Ca, Mg, Al, Si, Ti, Fe, Cr, Ni, Mn, Mo, Ce, Pr, Nd, Sm, Ta, W, and gas components (such as N, O, C and H) and the like as major impurities.

As shown in Table 1 and Table 5 below, the commercially available La (2N to 3N) used as the starting material contains Pb: 0.54 wtppm, Bi<0.01 wtppm, Th: 0.05 wtppm, and U: 0.04 wtppm, and the amount of α-ray reaches 0.00221 cph/cm² h.

Aluminum (Al) and Copper (Cu), contained in lanthanum as contaminants, are often used in alloy materials found in semi-conductor parts such as substrate, source and drain, and as such, can be a cause of malfunction if present in the gate material, even at a small amount. In addition, Iron (Fe) contained in lanthanum is readily oxidized and can cause defective sputtering when used as target. Furthermore, even if it is not oxidized while being inside the target, it could become oxidized after being sputtered. When this occurs, the volume expansion would lead to defects such as insulation failure and ultimately to malfunction. For all of these reasons, reduction of these contaminants is required.

The starting material contains large amounts of Fe and Al. As to Cu, it tends to contaminate through the water-cooling parts used when reducing chlorides and fluorides for the production of crude metals. In the lanthanum starting materials, these contaminating elements tend to exist as oxides.

In addition, as the lanthanum starting material, lanthanum fluoride or lanthanum oxide subjected to reduction by calcium is often used. Since the reducing agent calcium contains impurities such as Fe, Al and Cu, impurities from the reducing agent is often the source of contamination.

### (Molten Salt Electrolysis)

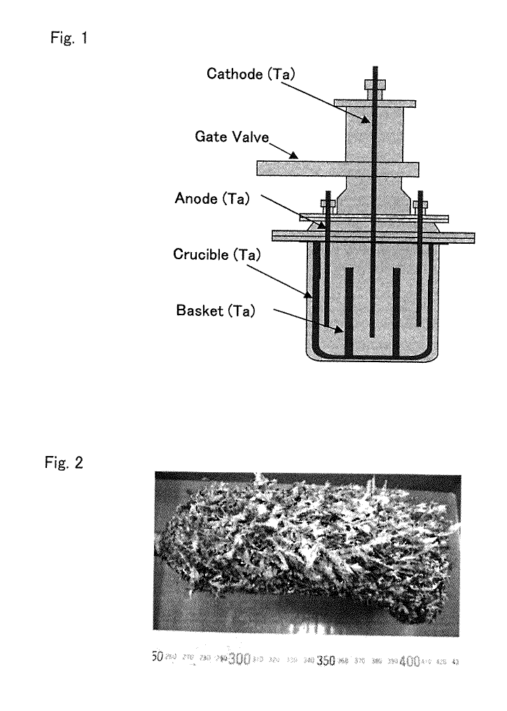

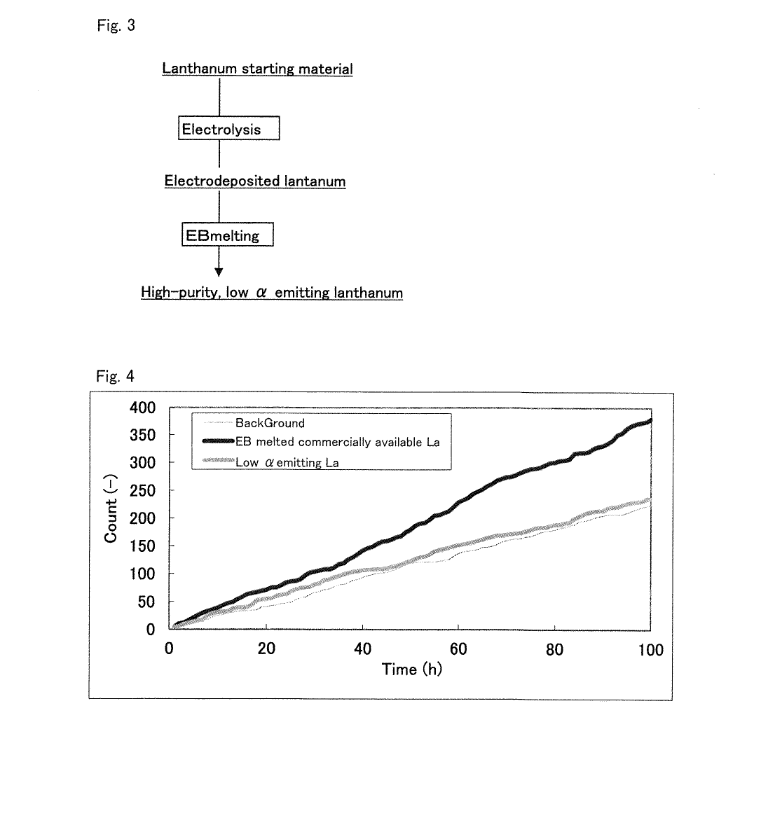

The invention of the present application performs molten salt electrolysis in order to increase the purity of the lanthanum and to achieve the purity of 5N or more. FIG. 1 is a diagram showing an example of molten salt electrolysis apparatus. As can be seen in FIG. 1, an anode made from Ta is placed at the bottom of the apparatus. Ta is used as a cathode.

Parts that come into contact with the electrolytic bath and electrodeposit are all made from Ta for preventing contamination. Ti, Ni and the like that are often used in molten salt electrolysis of other metals are not appropriate here because they tend to form an alloy with La.

A basket for separating the La starting material and electrodeposit is placed in the middle bottom part. Upper half of the apparatus is the cooling tower. This cooling tower and electrolysis tank is separated by a gate valve (GV).

As to the composition of the bath, one or more kind of potassium chloride (KCl), lithium chloride (LiCl), sodium chloride (NaCl), magnesium chloride (MgCl₂) and calcium chloride (CaCl₂) can be appropriately selected and used. In addition, lanthanum chloride (LaCl₂) can also be used as the electrolytic bath. The lanthanum chloride in this case is often added in order to ensure that the required lanthanum ion concentration of the bath is provided, in other words, to augment an insufficient amount of lanthanum contributed from the crude metallic lanthanum of the starting material. Accordingly, this (lanthanum chloride) is not treated as a raw material. As the raw material, crude metallic lanthanum is usually used.

The temperature of the electrolytic bath is preferably adjusted between 450 to 700° C. Although the bath temperature does not have a major impact on the electrolysis, high temperature causes increased evaporation of salt that constitute the bath, leading to the contamination of the gate valve and cooling tower. This should be avoided since cleaning can become too cumbersome.

On the other hand, handling becomes easier as the temperature is lowered. However, when the temperature is too low, it can cause a decrease in the fluidity of the bath, leading to an uneven distribution of the composition of the bath, and to a tendency of not being able to obtain a high-purity electrodeposit. Thus, the range mentioned above is the preferable range.

The atmosphere should be an inactive atmosphere. As to the material of the anode, a material that does not cause contamination is preferable. In that sense, the use of Ta is preferable. As to the material of the cathode, Ta is used. It is notable that in molten salt electrolysis of rare earths, graphite is generally used. However, this can cause contamination of carbon, and therefore should be avoided in the invention of the present application.

### (Conditions for Electrolysis)

Any current density can be chosen as long as it is within the range of 0.025 to 0.5 A/cm². Voltage was set at around 0.5V. However, since these conditions depend on the size of the apparatus, it is possible to set the conditions differently. Electrodeposit shown in FIG. 2 was obtained. Duration of the electrolysis is usually between 4 to 24 hours. When the molten salt electrolysis apparatus described above is used, electrodeposit weighing 150 to 500 g can be obtained.

### (Heating Furnace)

Using a heating furnace, metal and salt are separated by vacuum heating, taking advantage of the difference of vapor pressures. Normally, the desalting temperature is 850° C. or less. The temperature is maintained for 1 to 10 hours, however, depending on the amount of the raw material, it can be adjusted appropriately. By the desalting, the weight of the electrodeposited La was reduced by about 5 to 35%. The content of chloride (Cl) in the La after the desalting treatment was 50 to 3000 ppm.

### (Electron Beam Melting)

The electron beam melting of the above obtained lanthanum molded body is performed by wide range irradiation of a low power electron beam to the molten lanthanum starting material in a furnace. It is usually performed in the range of 9 kW to 32 kW. The electron beam melting can be repeated several times (two to four times). Repetition of the electron beam melting improves the removal of volatile elements such as Cl.

W, Mo and Ta cause an increase in the leak current and results in a decrease in the pressure-resistance. Therefore, for use in electronic parts, the total amount of these needs to be 10 wtppm or less.

Rare earth elements need to be removed from the high-purity lanthanum as described above, because it is technically very difficult to remove them during the production process of the high-purity lanthanum due to the similarity of chemical properties between lanthanum and other rare earth elements, and because it would not drastically alter the properties of the lanthanum even if there are some contaminations due to this similarity.

From these considerations, some contaminations of other rare earth elements are tolerated, up to a certain point. However, it goes without saying that it is preferable to keep the contamination to a minimum, in order to achieve improvement on the property of the lanthanum itself.

In addition, the reason for having a purity excluding gas components of 5N or more, is because removal of gas components is difficult and if it is incorporated into purity considerations, the purity would no longer reflect improvements in actual purity. Moreover, compared with other contaminating elements, their presence, up to a certain level, is harmless in general.

Sputtering is employed in many cases where a thin film is formed for use in electronic materials such as gate insulators and thin films for metal gate, and is considered to be a superior method for forming a thin film. Thus, producing a high-purity lanthanum sputtering target using the lanthanum ingot described above is an effective approach.

Target can be produced following the conventional processes including forging, rolling, cutting, finishing (grinding) and the like. There are no limitations to the production process and any processes can be appropriately selected.

A high-purity lanthanum having a purity of 5N or more excluding gas components, α-ray count number of 0.001 cph/cm² or less, and having Al, Fe and Cu each at an amount of 1 wtppm or less, and further having the total amount of impurities including W, Mo and Ta (materials for the crucible) of 10 wtppm or less, can thus be obtained.

In producing the target, the high-purity lanthanum ingot described above is first cut into prescribed size and then trimmed and grinded further.

Using the high-purity target thus obtained, a high-purity lanthanum film can be formed on a substrate by sputtering. As a result, a metal gate film having a high-purity lanthanum as the main component, having a purity of 5N or more excluding rare earth elements and gas components, and Al, Fe and Cu each at 1 wtppm or less can be formed on a substrate. The film on the substrate reflects the composition of the target, thus, allowing one to form a high-purity lanthanum film.

The metal gate film may be used as one having the same composition as the high-purity lanthanum described above, or alternatively, it can also be used as one formed in combination with other gate materials or as alloys or as compounds thereof. This can be accomplished by simultaneous sputtering using target made from other materials or sputtering using a mosaic target. The invention of the present application encompasses all of these possibilities. The contents of impurities vary depending on the amounts of impurities contained in the raw materials, however, by using the production method described above, it becomes possible to limit the impurities within the ranges described above.

The invention of the present application is a technique capable of efficiently and stably providing a high-purity lanthanum obtained above, a sputtering target comprising the high-purity lanthanum, and a metal gate thin film having the high-purity lanthanum as the main component and having α-ray count number of 0.001 cph/cm² or less

### Examples

Examples are now explained. These Examples are provided only for the purpose of explaining the invention better and are, not meant in any way to limit the present invention. In other words, other possible examples and transformations within the scope of the technological thought of the present invention are all considered to be included in the present invention.

### Example 1

As the lanthanum starting material to be processed, a commercially available product having a purity of 2N to 3N was used. The result of analysis of this lanthanum starting material is shown in Table 1. Lanthanum is a material that is drawing a lot of attention lately, however, commercially available products tends to lack consistency in terms of purity as well as quality. The commercially available product used herein is one of such products. As can be seen in Table 1, it contains Pb: 0.54 wtppm, Bi<0.01 wtppm, Th: 0.05 wtppm and U: 0.04 wtppm.

TABLE 1
Commercially available La (2N~3N)

| Element | wtppm |
|---|---|
| Li | 1200 |
| Be | 0.02 |
| B | 2.1 |
| F | <5 |
| Na | 4.3 |
| Mg | 33 |
| Al | 120 |
| Si | 160 |
| P | 6.4 |
| S | 50 |
| Cl | 1.8 |
| K | <0.01 |
| Ca | 0.99 |
| Sc | 0.01 |
| Ti | 5.7 |
| V | 0.28 |
| Cr | 21 |
| Mn | 36 |
| Fe | 330 |
| Co | 0.32 |
| Ni | 5.1 |
| Cu | 51 |
| Zn | <0.05 |
| Ga | <0.05 |
| Ge | <0.1 |
| As | <0.05 |
| Se | <0.05 |
| 8r | <0.05 |
| Rb | <0.01 |
| Sr | 0.02 |
| Y | 1.6 |
| Zr | 0.31 |
| Nb | <0.05 |
| Mo | 20 |
| Ru | <0.05 |
| Rh | <0.05 |
| Pd | <0.05 |
| Ag | <0.01 |
| Cd | <0.05 |
| In | <0.05 |
| Sn | <0.05 |
| Sb | <0.05 |
| Te | <0.05 |
| I | <0.05 |
| Cs | <0.1 |
| Ba | <1 |
| La | |
| Ce | 700 |
| Pr | 37 |
| Nd | 170 |
| Sm | 220 |
| Eu | <0.05 |
| Gd | 3 |
| Tb | 0.15 |
| Dy | 9.6 |
| Ho | 0.07 |
| Er | 0.16 |
| Tm | <0.05 |
| Yb | <0.05 |
| Lu | <0.05 |
| Hf | <0.05 |
| Ta | 35 |
| W | 4.8 |
| Re | <0.05 |
| Os | <0.05 |
| Ir | <0.05 |
| Pt | <0.05 |
| Au | <0.5 |
| Hg | <1 |
| Tl | <0.05 |
| Pb | 0.54 |
| Bi | <0.01 |
| Th | 0.05 |
| U | 0.04 |
| C | 920 |
| N | <10 |
| O | 90 |
| S | <10 |
| H | 26 |

### (Molten Salt Electrolysis)

Molten salt electrolysis was performed using the starting material. An apparatus depicted in FIG. 1 above was used in the molten salt electrolysis. As to the composition of the bath, 40 kg of potassium chloride (KCl), 9 kg of lithium chloride (LiCl), 15 kg of calcium chloride (CaCl₂), 6 kg of lanthanum chloride (LaCl₃) and 10 kg of La starting material were used.

The temperature of the electrolytic bath was between 450 to 700° C., and for this example, was adjusted to 600° C. The temperature of the bath had no significant effect on the electrolysis. In addition, at this temperature, the evaporation of salt was minimal, and no severe contamination of gate valve and cooling tower was observed. An inactive gas was used as the atmosphere.

Electrolysis was performed at current density of 0.41 A/cm², and voltage of 1.0 V. The crystal form is shown in FIG. 2. The duration of electrolysis was for 12 hours. Thus, 500 g of electrodeposited material was obtained.

The result of analysis of the deposit obtained by the electrolysis is shown in Table 2. As expected for the result of molten salt electrolysis, Table 2 shows extremely high concentrations of chloride and oxygen while low concentrations for other contaminants.

TABLE 2
Electrolytic deposit

| Element | wtppm |
|---|---|
| Li | 14 |
| Be | <0.01 |
| B | 0.04 |
| F | <5 |
| Na | <0.05 |
| Mg | <0.05 |
| Al | 0.09 |
| Si | 0.38 |
| P | 0.16 |
| S | 4.1 |
| Cl | ~550 |
| K | 16 |
| Ca | 22 |
| Sc | <0.005 |
| Ti | 0.53 |
| V | 0.07 |
| Cr | <0.05 |
| Mn | <0.01 |
| Fe | 0.5 |
| Co | 0.34 |
| Ni | 0.27 |
| Cu | 0.44 |
| Zn | <0.05 |
| Ga | <0.05 |
| Ge | <0.1 |
| As | <0.05 |
| Se | <0.05 |
| Br | <0.05 |
| Rb | <0.01 |
| Sr | <0.01 |
| Y | 0.61 |
| Zr | 0.02 |
| Nb | 0.35 |
| Mo | <0.05 |
| Ru | 0.13 |
| Rh | <0.05 |
| Pd | <0.05 |
| Ag | <0.01 |
| Cd | <0.05 |
| In | <0.05 |
| Sn | <0.05 |
| Sb | <0.05 |
| Te | <0.05 |
| I | <0.05 |
| Cs | <0.1 |
| Ba | <1 |
| La | |
| Ce | 24 |
| Pr | 1.8 |
| Nd | 2 |
| Sm | <0.05 |
| Eu | <0.05 |
| Gd | 19 |
| Tb | 3.3 |
| Dy | <0.05 |
| Ho | <0.05 |
| Er | 0.09 |
| Tm | <0.05 |
| Yb | <0.05 |
| Lu | <0.05 |
| Hf | <0.05 |
| Ta | 3.5 |
| W | 0.25 |
| Re | <0.05 |
| Os | <0.05 |
| Ir | <0.05 |
| Pt | <0.05 |
| Au | <0.5 |
| Hg | <0.1 |
| Tl | <0.05 |
| Pb | 0.04 |
| Bi | <0.01 |
| Th | <0.001 |
| U | <0.001 |
| C | 130 |
| N | 35 |
| O | 9400 |
| S | <10 |
| H | 420 |

### (Desalting Treatment)

The electrodeposited material was vacuum heated using a heating furnace, and metal and salt were separated using the difference of vapor pressures. The temperature at which the desalting was carried out was set at 850° C. The temperature was held for 4 hours. The weight of electrodeposited La was reduced about 20% by the desalting. The chloride (Cl) content of La after the desalting treatment was 160 ppm.

### (Electron Beam Melting)

Next, the desalted lanthanum thus obtained was subjected to electron beam melting. This is performed by the extensive irradiation of a low power electron beam to the molten lanthanum starting material in a furnace. The irradiation was performed at the degree of vacuum of 6.0×10⁻⁵ to 7.0×10⁻⁴ mbar, and the melting power of 32 kW. The electron beam melting was repeated twice. The duration of EB melting was 30 minutes each. EB melt ingot was thus produced. High volatile substance was removed by evaporation during the EB melting. The removal of volatile components such as Cl became thus possible.

High-purity lanthanum was thus produced. The result of analysis of the high-purity lanthanum is shown in Table 3. As Table 3 shows, reduction of the following was achieved; Pb: 0.04 wtppm, Bi<0.01 wtppm, Th<0.001 wtppm and U<0.001 wtppm.

In addition, Al<0.05 wtppm, Fe: 0.18 wtppm, and Cu: 0.12 wtppm were achieved. The numbers all satisfied the requirements for the invention of the present application of 1 wtppm or less.

Since Pb and Bi emit α-ray by atomic decay, the reduction of Pb and Bi is effective in reducing the amount of α-ray. In addition, since Th and U are radioactive substances, their reduction is also effective in reducing α-ray. As shown in Table 5 below, the amount of α-ray was reduced to 0.00017 cph/cm², achieving the requirement of α-ray count number of 0.001 cph/cm² or less of the invention of the present application.

TABLE 3
High-purity lanthanum

| Elements | wtppm |
|---|---|
| U | 0.16 |
| Be | <0.01 |
| B | <0.01 |
| F | <5 |
| Na | <0.05 |
| Mg | <0.05 |
| Al | <0.05 |
| Si | 0.21 |
| P | 0.03 |
| S | 2.1 |
| Cl | 4.9 |
| K | <0.01 |
| Ca | <0.05 |
| Sc | <0.005 |
| Ti | 0.97 |
| V | <0.005 |
| Cr | <0.05 |
| Mn | <0.01 |
| Fe | 0.18 |
| Co | 0.03 |
| Ni | 0.47 |
| Cu | 0.12 |
| Zn | 0.06 |
| Ga | <0.05 |
| Ge | <0.1 |
| As | <5 |
| Se | <0.05 |
| Br | <0.05 |
| Rb | <0.01 |
| Sr | <0.01 |
| Y | 1.5 |
| Zr | <0.01 |
| Nb | <0.05 |
| Mo | <0.05 |
| Ru | <0.05 |
| Rh | <0.05 |
| Pd | <0.05 |
| Ag | <0.01 |
| Cd | <0.05 |
| In | <0.05 |
| Sn | <0.05 |
| Sb | <0.05 |
| Te | <0.05 |
| I | <0.05 |
| Cs | <0.1 |
| Ba | <1 |
| La | |
| Ce | 17 |
| Pr | 3 |
| Nd | 8.2 |
| Sm | <0.05 |
| Eu | 0.29 |
| Gd | 0.71 |
| Tb | 3.4 |
| Dy | 0.13 |
| Ho | 0.53 |
| Er | 0.06 |
| Tm | <0.05 |
| Yb | <0.05 |
| Lu | <0.05 |
| Hf | <0.05 |
| Ta | 2.8 |
| W | 0.12 |
| Re | <0.05 |
| Os | <0.05 |
| Ir | <0.05 |
| Pt | <0.05 |
| Au | <0.5 |
| Hg | <0.1 |
| Tl | <0.05 |
| Pb | 0.04 |
| Bi | <0.01 |
| Th | <0.001 |
| U | <0.001 |
| C | 130 |
| N | <10 |
| O | 440 |
| S | <10 |
| H | 3.2 |

The effect of reducing major impurities was as follows. Li: 0.16 wtppm, Na<0.05 wtppm, K<0.01 wtppm, Ca<0.05 wtppm, Mg<0.05 wtppm, Si: 0.21 wtppm, Ti: 0.97 wtppm, Ni: 0.47 wtppm, Mn<0.01 wtppm, Mo<0.05 wtppm, Ta: 2.8 wtppm, W: 0.12 wtppm, Pb: 0.04 wtppm, Bi<0.01 wtppm, U<0.001 wtppm and Th<0.001 wtppm. In addition, the preferred requirement of the total amount of W, Mo and Ta of 10 wtppm or less of the invention of the present application was also achieved.

The lanthanum ingot thus obtained was subjected to a hot press as required, followed by machine processing, and grinding to produce a disc like target having a dimension of ø140×14t. The weight of the target was 1.42 kg. This was then joined with a backing plate to form a sputtering target. The target for high-purity lanthanum sputtering having the composition described above and having low α-ray amount, was thus obtained. Since the target is highly prone to oxidization, it is preferable to vacuum pack it for storage or transportation.

The result of the time course measurements of α-ray due to α decay, of background control, commercially available La and low a emitting La of the Example, are shown in FIG. 4.

For α-ray measurements, samples having a prescribed surface area were placed within a chamber injected with an inactive gas such as Ar, and the total number of α-ray count was measured during a specified duration, usually between 50 to 200 hours. FIG. 4 also shows the measured values for the background (natural radiation) as well as those obtained with commercially available lanthanum (La). The data for background (natural radiation) was measured by a measuring apparatus in the absence of the sample for the same time duration.

It is apparent from FIG. 4 that the measurements for low a emitting lanthanum are slightly above those for the background control. These values are deemed to be sufficiently low. On the other hand, data from the commercially available La shows a gradual increase in the number of α-ray counts as time passes.

### Comparative Example 1

As the lanthanum starting material to be processed, a commercially available product having a purity of 2N to 3N was used. In this case, a lanthanum starting material having the same purity as that of Example 1 shown in Table 1 was used. The commercial lanthanum used in Comparative Example 1 was in tabular form with a dimension of 120 mm square×30 mm t. The weight of one tablet was 2.0 kg to 3.3 kg. Total of 12 such tablets, equivalent to 24 kg of the starting material was used. These tabular lanthanum starting materials were packed in vacuum since they were highly prone to oxidization.

Next, the starting material was melted in a EB melting furnace at the melting power of 32 kW, and an ingot was produced at a molding speed of 13 kg/h. Substances having high volatility were evaporated and removed during the EB melting process. A high-purity lanthanum ingot of 22.54 kg, was thus produced. The results of analysis of the lanthanum thus obtained are shown in Table 4.

As can be seen in Table 4, Pb: 0.24 wtppm, Bi<0.01 wtppm, Th: 0.011 wtppm and U: 0.0077 wtppm, values that are larger than those of Examples, were observed.

The lanthanum had Al of 72 wtppm, Fe of 130 wtppm and Cu of 9.2 wtppm. These values did not satisfy the requirement of 1 wtppm or less each, of the invention of the present application. Thus, the goal of the invention of the present application was not achieved merely by subjecting the commercially available La to EB melting. In addition, α-ray count number was 0.00221 cph/cm², and the requirement of α-ray count number of 0.001 cph/cm² or less of the invention of the present application was not achieved.

Major impurities included the following: Li:12 wtppm, Na:0.86 wtppm, K<0.01 wtppm, Ca<0.05 wtppm, Mg:2.7 wtppm, Si:29 wtppm, Ti:1.9 wtppm, Cr:4.2 wtppm, Ni:6.3 wtppm, Mn: 6.4 wtppm, Mo:8.2 wtppm, Ta:33 wtppm, W:0.81 wtppm, U:0.0077 wtppm and Th:0.011 wtppm.

TABLE 4
EB melted La

| Element | wtppm |
|---|---|
| Li | 12 |
| Be | <0.01 |
| B | 0.9 |
| F | <5 |
| Na | 0.86 |
| Mg | 2.7 |
| Al | 72 |
| Si | 29 |
| P | 2.6 |
| S | 30 |
| Cl | 0.31 |
| K | <0.01 |
| Ca | <0.05 |
| Sc | <0.005 |
| Ti | 1.9 |
| V | 0.29 |
| Cr | 4.2 |
| Mn | 6.4 |
| Fe | 130 |
| Co | 0.02 |
| Ni | 6.3 |
| Cu | 9.2 |
| Zn | 0.09 |
| Ga | <0.05 |
| Ge | <0.1 |
| As | 0.82 |
| Se | <0.05 |
| Br | <0.05 |
| Rb | <0.01 |
| Sr | <0.01 |
| Y | 2.2 |
| Zr | 0.22 |
| Nb | <0.05 |
| Mo | 8.2 |
| Ru | <0.05 |
| Rh | <0.05 |
| Pd | <0.05 |
| Ag | <0.01 |
| Cd | <0.05 |
| In | <0.05 |
| Sn | <0.05 |
| Sb | <0.05 |
| Te | <0.05 |
| I | <0.05 |
| Cs | <0.1 |
| Ba | <1 |
| La | |
| Ce | 410 |
| Pr | 25 |
| Nd | 65 |
| Sm | 36 |
| Eu | <0.05 |
| Gd | 1.5 |
| Tb | 0.09 |
| Dy | 1 |
| Ho | 0.08 |
| Er | 0.18 |
| Tm | <0.05 |
| Yb | 2 |
| Lu | 0.14 |
| Hf | <0.05 |
| Ta | 33 |
| W | 0.81 |
| Re | <0.05 |
| Os | <0.05 |
| Ir | <0.05 |
| Pt | <0.05 |
| Au | <0.5 |
| Hg | <0.1 |
| Tl | <0.05 |
| Pb | 0.24 |
| Bi | <0.01 |
| Th | 0.011 |
| U | 0.0077 |
| C | 700 |
| N | <10 |
| O | 320 |
| S | 13 |
| H | 23 |

TABLE 5

| | EB melted commercially | |
|---|---|---|
| | availabe La | Low α emitting La |
| Pb (ppm) | 0.54 | 0.04 |
| Bi (ppm) | <0.01 | <0.01 |
| Th (ppm) | 0.05 | <0.001 |
| U (ppm) | 0.04 | <0.001 |
| Amount of α ray | 0.00221 | 0.00017 |
| (c/cm²h) | | |

### INDUSTRIAL APPLICABILITY

The high-purity lanthanum, the sputtering target produced from the high-purity lanthanum, and the thin film for metal gate having the high-purity lanthanum as the main component, obtained by the present invention have α-ray count number of 0.001 cph/cm² or less thereby excluding the influence of α-ray to the semi-conductor chip as much as possible. Accordingly, the occurrence of software error due to the effect of α-ray in the semi-conductor apparatus is significantly reduced and functions of electronic apparatus are not hindered or interfered. As such, they are useful as the materials for gate insulator or metal gate thin film.

1. A high-purity lanthanum, characterized by having a purity of 5N or more excluding rare earth elements and gas components, and α-ray count number of 0.001 cph/cm² or less.

2. The high-purity lanthanum according to claim 1, characterized by having Pb content of 0.1 wtppm or less, Bi content of 0.01 wtppm or less, Th content of 0.001 wtppm or less, and U content of 0.001 wtppm or less.

3. The high-purity lanthanum according to claim 2, characterized by having Al, Fe, Cu contents of 1 wtppm or less, respectively.

4. The high-purity lanthanum according to claim 3, characterized by having a total content of W, Mo and Ta of 10 wtppm or less.

5. A sputtering target comprising the high-purity lanthanum according to claim 1.

6. A metal gate film formed from the sputtering target according to claim 5.

7. A semi-conductor element or device equipped with the metal gate film according to claim 6.

8. A method for producing high-purity lanthanum, comprising the steps of: obtaining lanthanum crystal by subjecting a crude lanthanum metal raw material having a purity of 4N or less excluding gas components to molten salt electrolysis at a bath temperature of 450 to 700° C., subjecting the lanthanum crystal to de-salting treatment, and removing volatile substances by performing electron beam melting, wherein the high-purity lanthanum has a purity of 5N or more excluding rare earth elements and gas components, and α-ray count number of 0.001 cph/cm² or less.

9. The method for producing the high-purity lanthanum according to claim 8, characterized by using a electrolytic bath comprising potassium chloride (KCl), lithium chloride (LiCl), sodium chloride (NaCl), magnesium chloride (MgCl₂), calcium chloride (CaCl₂) and lanthanum chloride (LaCl₃), as the molten salt electrolytic bath.

10. The method for producing the high-purity lanthanum according to claim 9, characterized by performing the molten salt electrolysis using an anode that is made from Ta.

11. The method for producing the high-purity lanthanum according to claim 10, characterized by performing de-salting treatment that separates metal and salt utilizing difference in vapor pressures by vacuum heating in a heating furnace at a temperature of 850° C. or less.

12. The method for producing high-purity lanthanum according to claim 8, wherein an anode made of Ta is used in the molten salt electrolysis.

13. The method for producing high-purity lanthanum according to claim 12, wherein, during the de-salting treatment, metal and salt are separated based on a difference of their vapor pressures by vacuum heating in a heating furnace at a temperature of 850° C. or less.

14. The method for producing high-purity lanthanum according to claim 8, wherein, during the de-salting treatment, metal and salt are separated based on a difference of their vapor pressures by vacuum heating in a heating furnace at a temperature of 850° C. or less.

15. The high-purity lanthanum according to claim 1, characterized by having Al, Fe, Cu contents of 1 wtppm or less, respectively.

16. The high-purity lanthanum according to claim 15, characterized by having a total content of W, Mo and Ta of 10 wtppm or less.

17. The high-purity lanthanum according to claim 1, characterized by having a total content of W, Mo and Ta of 10 wtppm or less.
